(19) United States
(12) Patent Application Publication
(10) Pub. No.: US 2003/0024115 A1
(43) Pub. Date: Feb. 6, 2003

(54) Circuit board packaging process for obstructing electromagnetic wave

(75) Inventor: Dennis Shiau, Taichung Hsien (TW)

Correspondence Address: BROWDY AND NEIMARK, P.L.L.C., 624 NINTH STREET, NW, SUITE 300, WASHINGTON, DC, 20001-5303, US

(73) Assignee: Power Mate Technology Co., Ltd., Taichung (TW)

(21) Appl. No.: 09/930,211

(22) Filed: Aug. 16, 2001

(30) Foreign Application Priority Data
Jul. 6, 2001 (TW) 90116536

(51) Int. Cl. H05K 3/20; H01K 3/22

(52) U.S. Cl. 29/848; 29/831; 29/852

(57) ABSTRACT

A circuit board packaging process comprises the steps of: (a) connecting a circuit board with a plurality of pins by soldering; (b) attaching a metal housing to the cavity of the lower mold of a molding tool, the lower mold cavity has a resin feeding port; the metal housing has a through hole corresponding in location to the resin feeding port; (c) attaching a metal piece to the upper mold of the molding tool; the metal piece has a plurality of through holes for receiving therethrough the pins; the upper mold cavity has a plurality of insertion holes corresponding in location to the through holes; the circuit board is retained under the metal piece such that the pins are inserted into the insertion holes via the through holes; (d) closing the upper and the lower molds to enable the circuit board to be located between the metal piece and the metal housing; (e) injecting resin toward the through hole from the resin feeding port; (f) upon completion of the cooling of the molding tool, removing a finished product from the mold.

### FIELD OF THE INVENTION

The present invention relates generally to a circuit board packaging process, and more particularly to a circuit board packaging process for hindering the electromagnetic wave.

### BACKGROUND OF THE INVENTION

The conventional process for packaging the circuit board involves a step in which a loaded circuit board is placed on a molding machine. In the meantime, the hot resin is ready to be poured into the machine via the feeding port. The machine is started to close the upper mold and the lower mold before the semimoldten resin is injected into the mold. As the resin is hardened, the mold is opened to remove therefrom the finished product. The process takes place by a complete packaging mode. The wires of the interior of the circuit board carry out the signal transmission via the resin layer. Under this circumstance and without the protection of the metal layer, the wires of the circuit board do not cool easily. The system operation is susceptible to electromagnetic interference (EMI), thereby resulting in instability of entire device system.

With a view to improve the above deficiency, the resin injection operation takes place in a metal housing in which the circuit board is disposed. The insulating substrate is sputtered or embedded with a copper piece for obstructing the electromagnetic wave as well as enhancing the cooling of the wires. As shown in FIGS. 1 and 2, the resin 79 is manually injected into a metal housing 70 such that a predetermined space 71 is preserved, and that an assembled circuit board (not shown in drawing) is disposed in the space 71. As shown in FIG. 2, the substrate 77 which has been sputtered or embedded a copper piece 75 is kept on the metal housing 70, thereby enabling the circuit board to be covered by the resin 79. The finished product is held securely by a plurality of clamping bodies 78 such that the substrate 77 is not spilled by the resin. The finished product is rested without disturbance for over 10 hours. As the resin becomes hardened, the packaging process is completed.

The formation of the passivation film by sputtering or embedding the copper piece to obstruct the electromagnetic wave is time-consuming. In addition, the resin injection often results in formation of voids responsible for the breakdown of the circuit board under the circumstance of expansion and contraction. As a result, the rejection rate of the circuit board increases.

In addition, the metal housing must be sealed off upon completion of resin injection, thereby resulting in an increase in material cost and molding tool cost. Moreover, the assembly of the substrate is labor intensive and costly.

### SUMMARY OF THE INVENTION

It is the primary objective of the present invention to provide a circuit board packaging process which results in low rejection rate and obstruction of the electromagnetic wave.

It is another objective of the present invention to provide a circuit board packaging process which reduces the cost of the resin packaging of the circuit board.

The process of the present invention involves a first step in which a circuit board and a predetermined pin are vertically connected by soldering. A metal housing is attached to the lower mold cavity of a molding tool. The lower mold cavity is provided with a resin feeding port corresponding in location to a through hole of the metal housing. The upper mold of the molding tool is provided with a metal piece which has a through hole corresponding in location to the pin. The upper mold cavity has a plurality of insertion holes corresponding in location to the pins. The circuit board is retained under the metal piece such that the pins are inserted into the insertion holes via the through holes. The upper mold is joined with the lower mold such that the circuit board is located between the metal piece and the metal housing. The metal piece is attached to the periphery of the metal housing. The resin is injected into the metal housing via the resin feeding port of the lower mold and the through hole of the metal housing. Upon completion of the cooling of the molding tool, the molding tool is opened to remove therefrom the finished product.

### BRIEF DESCRIPTION OF THE DRAWINGS

FIG. 1 shows a schematic view of a prior art packaging process.

FIG. 2 shows an exploded view of the copper piece embedded in the metal housing of the prior art packaging process.

FIG. 3 shows a perspective view of the semifinished product of the circuit board and the pins of a preferred embodiment of the present invention.

FIG. 4 shows an exploded view of the molding tool of the preferred embodiment of the present invention.

FIG. 5 shows a schematic plan view of the metal piece of the preferred embodiment of the present invention.

FIG. 6 shows a schematic view of the resin packaging of the circuit board in the molding tool of the present invention.

FIG. 7 shows a schematic view of the finished product of the preferred embodiment of the present invention.

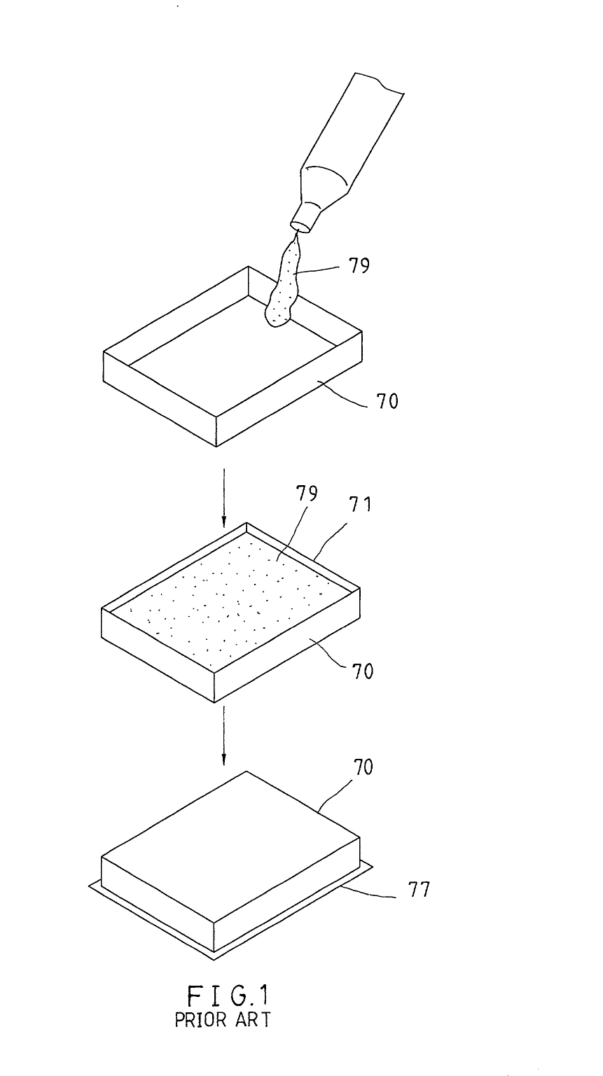

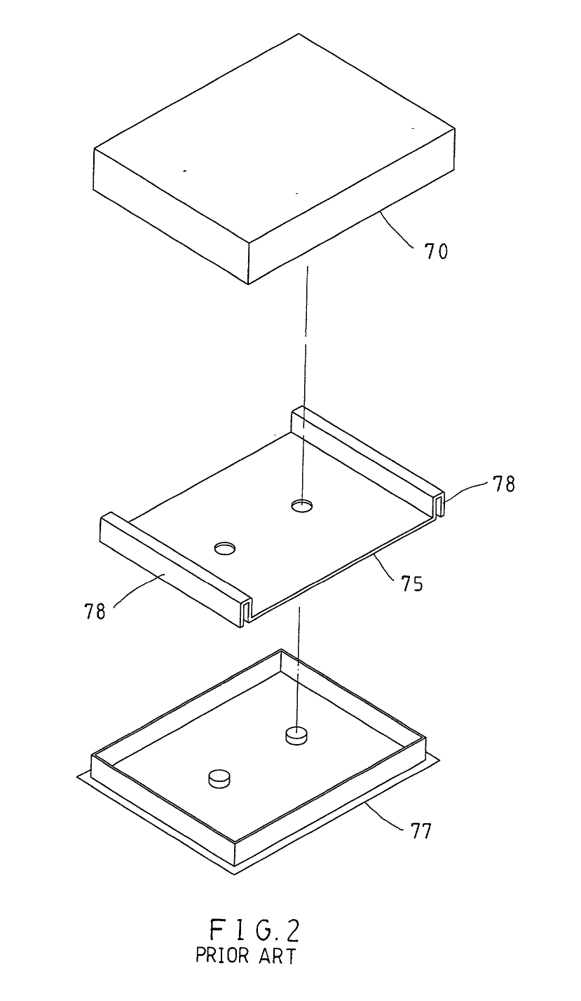

### DETAILED DESCRIPTION OF THE INVENTION

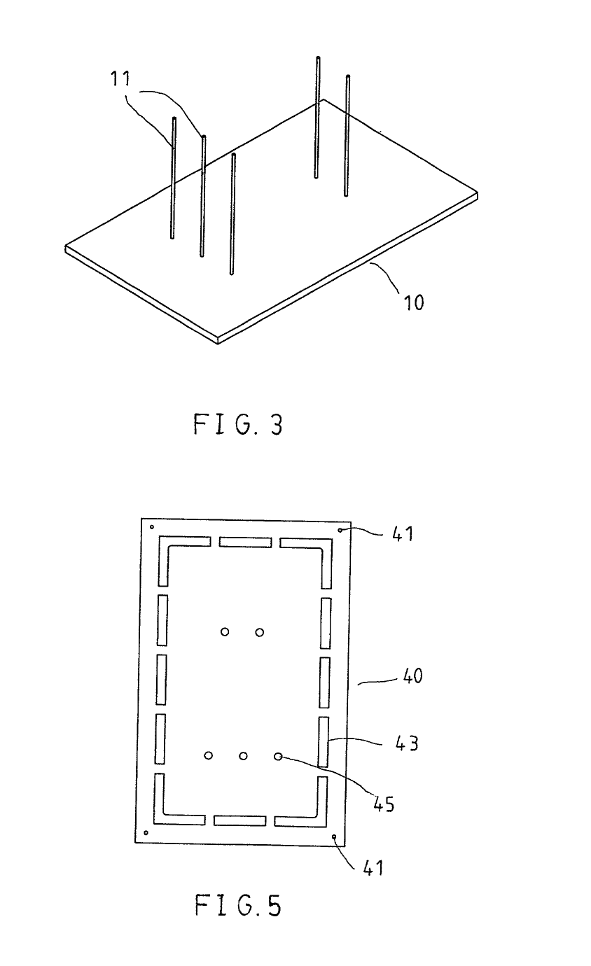

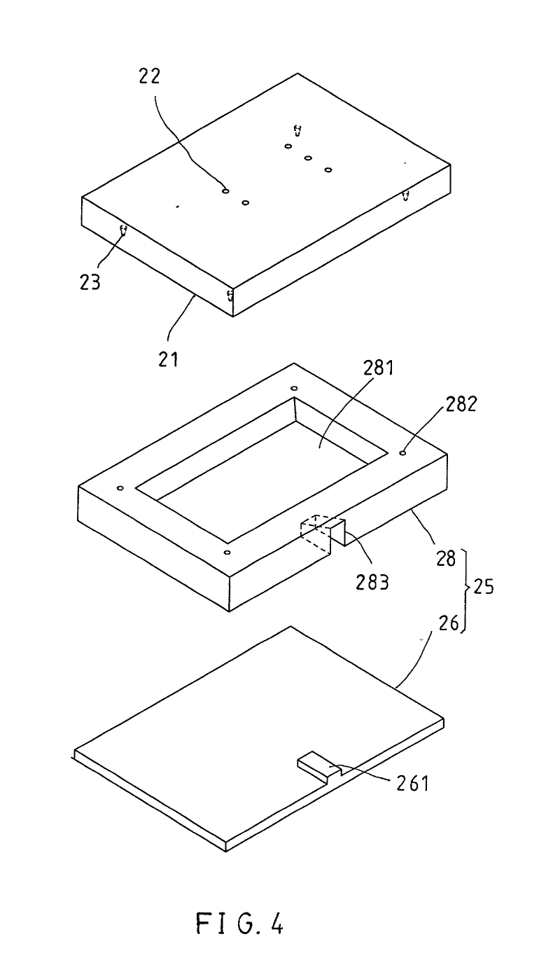

As shown in FIGS. 3-7, the process of the present invention comprises a first step in which the wired circuit board 10 is provided thereon with five pins 11 connected therewith by soldering, as shown in FIG. 3. As shown in FIG. 4, a molding tool 20 has an upper hold 21 and a lower mold 25 comprising a flat board 26 and a grilled fence 28. The flat board 26 is provided with a protruded block 261. The grilled fence 28 is provided in the center with a receiving slot 281, and in tops of four corners with a cavity 282. The receiving slot 281 is provided with a resin feeding port 283 having a tapered top. A metal housing 30 is disposed in the receiving slot 281 such that the periphery of the metal housing is in contact with the inner wall of the receiving slot 281. The metal housing 30 has a through hole 31 corresponding in location to the resin feeding port 283.

The upper mold 21 has a recessed portion 211 which is provided with five insertion holes 22 corresponding to the pins 11. The upper mold 21 is further provided with four protruded pillars 23 corresponding to the cavities 282. A metal piece 40, as shown in FIG. 5, is provided with four locating holes 41 opposite to the four protruded pillars 23. As shown in FIG. 5, a metal piece 40 is provided with a plurality of hollowed portions 43 corresponding to the fringe of the metal housing 30. The metal piece 40 is provided in the center with five through holes 45 opposite to the insertion holes 22. The pins 11 of the circuit board 10 are inserted into the insertion holes 22 via the through holes 45 of the metal piece 40. The protruded pillars 23 are retained in the locating holes 41. The circuit board 10 is located under the metal piece 40.

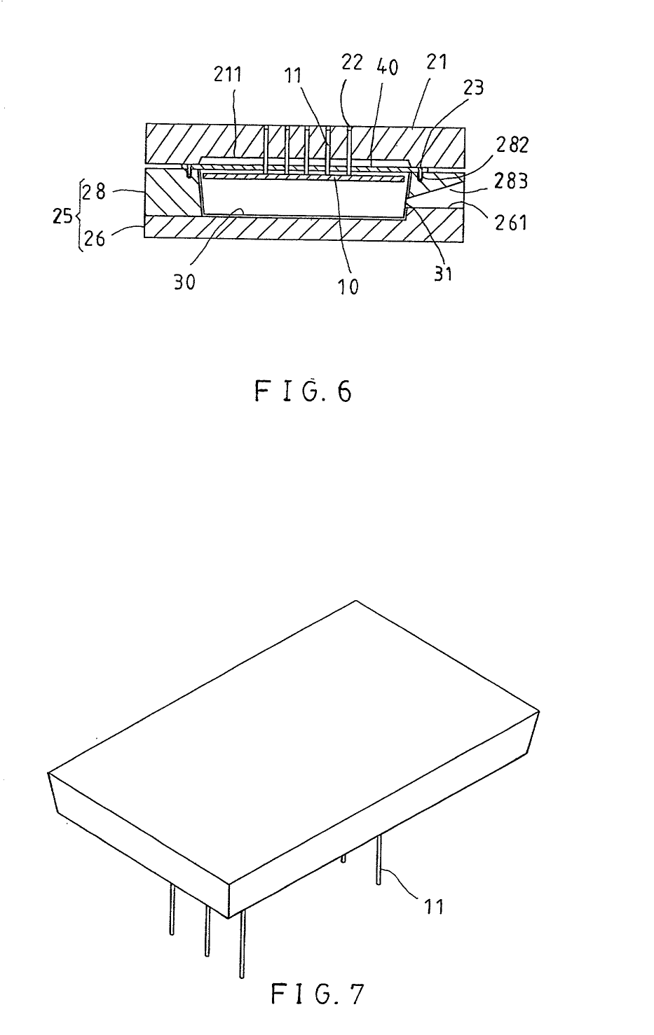

As shown in FIG. 6, the upper mold 21 is joined with the lower mold 25. The protruded block 261 is inserted into the feeding port 283 to form a tapered channel. The protruded pillars 23 are inserted into the cavities 282. The circuit board 10 is located between the metal piece 40 and the metal housing 30. The underside of the metal piece 40 is attached to the periphery of the metal housing 30. The metal piece 40 is secured in place between the upper mold 21 and the lower mold 25 by the locating holes 41.

The resin is injected into the metal housing 30 via the feeding port 283 of the lower mold 25 and the through hole 31 of the metal housing 30. The interior of the metal housing 30 is filled with resin such that the resin flows into the recessed portion 211 of the upper mold 21 via the hollowed portion 43 of the metal piece 40. Upon completion of the cooling of the molding tool 20, the molding tool is opened to remove therefrom the finished product.

The present invention further comprises a step in which the metal piece 40 located in the outer side of the fringe of the metal housing 30 is removed along the hollowed portions 43. The finished product is shown in FIG. 7.

The circuit board 10 is retained in the upper mold 21 by the pins 11. The metal piece 40 is sandwiched between the upper mold 21 and circuit board 10. The resin injection is done with ease. The locating holes 41 of the metal piece 40 enable the metal piece 40 to be located when the molding tool is closed. The hollowed portions 43 facilitate the cutting operation.

The present invention has a low rejection rate. The metal housing and the circuit board are integrally formed to eliminate the voids. In addition, the present invention is cost-effective such that the present invention does not call for the use of a substrate to seal off the metal housing.

What is claimed is:

1. A circuit board packaging process comprising the steps of:
(a) connecting a circuit board with a plurality of pins by soldering;
(b) attaching a metal housing to the mold cavity of the lower mold of a molding tool, the mold cavity having a resin feeding port corresponding in location to a through hole of the metal housing;
(c) retaining a metal piece in the upper mold of the molding tool, the metal piece having a plurality of through holes corresponding to the pins, the upper mold cavity having a plurality of insertion holes corresponding in location to the pins, the circuit board being disposed under the metal piece such that the pins are inserted into the insertion holes via the through holes;
(d) closing the molding tool such that the circuit board is located between the metal piece and the metal housing, and that the metal piece is in contact with the metal housing;
(e) injecting resin into the metal housing via the feeding port of the lower mold;
(f) opening the cooled mold to remove therefrom a finished product.

2. The process as defined in claim 1, wherein the upper mold is provided in the fringe with at least one protruded pillar; wherein said metal piece is provided in the fringe with at least one locating hole corresponding in location to the protruded pillar; wherein the lower mold is provided with at least one cavity for receiving the protruded pillar.

3. The process as defined in claim 2, wherein the metal piece is provided with a plurality of hollowed portions along the fringe of the metal housing.

4. The process as defined in claim 3, wherein the aftermath of the step (f) comprises a step (g) in which the portion of the metal piece located in the outer side of the fringe of the metal housing is removed along the hollowed portion.

5. The process as defined in claim 2, wherein the lower mold comprises a flat board which is provided with a grilled fence forming a receiving slot having a resin feeding port; wherein the cavities are disposed at four comers of the top of the fence.
